(19) United States
(12) Patent Application Publication
(10) Pub. No.: US 2014/0352769 A1
(43) Pub. Date: Dec. 4, 2014

(54) Edge Counter-Doped Solar Cell With Low Breakdown Voltage

(71) Applicant: Varian Semiconductor Equipment Associates, Inc., Gloucester, MA (US)

(72) Inventor: Nicholas P.T. Bateman, Reading, MA (US)

(21) Appl. No.: 13/904,163

(22) Filed: May 29, 2013

(51) Int. Cl. H01L 31/0352; H01L 31/18

(52) U.S. Cl. CPC H01L 31/03529; H01L 31/18
USPC 136/255; 438/57

(57) ABSTRACT

A solar cell having a large region where reverse breakdown can occur is disclosed. Reverse breakdown tends to occur near areas where heavily doped n-type regions abut heavily doped p-type regions. Thus, by increasing the region where such a heavily doped p/n junction exists may improve the reverse breakdown characteristics of the solar cell. In addition, a method of making such solar cell is disclosed, where this heavily doped p/n junction is fabricated along at least a portion of the perimeter of the solar cell.

Embodiments of the present invention relate to methods and apparatus for improving or reducing break down voltage in solar cells.

### BACKGROUND

Solar cells operate by creating mobile electron/hole pairs when impinged by light or photons. However, each solar cell has limited ability to generate power. Thus, solar cells are typically arranged in banks, where all of the solar cells are connected in series. In this way, voltage produced by each solar cell is added to that produced by every other solar cell in the bank to create a significant output voltage.

However, typically 5% of the solar cells in a bank may be in shade, and not receiving any light. Thus, these cells are not generating any current. However, since these shaded cells are in series with other current-producing cells, they must pass this current, while operating in reverse bias mode. Typical solar cells are capable of producing more than 7 amps at the maximum power point. A bank of 12 solar cells, for example, may produce more than 5 volts at these currents. Thus, it is possible that a shaded solar cell may need to dissipate in excess of 30 watts.

If this power is dissipated over a small area, the thermal excursion can easily be extreme and lead to melting or other failures. Several approaches are used to alleviate this problem. In some cases, this can be managed by requiring solar cells to have a reverse bias current lower than 1 amp at −10V. This limits the thermal load by forcing all solar cells to high voltage/low current operation. While this limits the thermal load, it also limits the current produced by the entire array of solar cells to about 1 amp. Thus, a bank of 12 solar cells may only generate about 10W, if one or more of the cells are shaded.

Another approach is to ensure that all solar cells have a low breakdown voltage, such as 3.5V. This approach may serve to limit the power dissipated by a shaded solar cell. However, this technique is only acceptable if the reverse current passes through a large area of the solar cell, so that the power dissipation is spread out and there are no local hot spots, where a significant amount of the power is dissipated.

Thus, a solar cell having a large area where reverse breakdown occurs is needed. In addition, a method for making such a solar cell would also be beneficial.

### SUMMARY

A solar cell having a large region where reverse breakdown can occur is disclosed. Reverse breakdown tends to occur near areas where heavily doped n-type regions abut heavily doped p-type regions. Thus, by increasing the region where such a heavily doped p/n junction exists may improve the reverse breakdown characteristics of the solar cell. In addition, a method of making such solar cell is disclosed, where this heavily doped p/n junction is fabricated along at least a portion of the perimeter of the solar cell.

According to one embodiment, a solar cell is disclosed, comprising a substrate having a first surface, an opposite second surface and a plurality of edges between the first surface and the second surface, wherein a linear length of the plurality of edges defines a perimeter of the substrate, the substrate having a first conductivity; a first heavily doped region, having a second conductivity, opposite the first conductivity, disposed on the first surface and extending along the edges; and a second heavily doped region, having the first conductivity, disposed on the second surface and extending along the edges under the first heavily doped region, such that a p/n junction is formed along at least 40% of the perimeter.

According to a second embodiment, a solar cell is disclosed, comprising a substrate having a front surface, an opposite back surface and a plurality of edges between the front surface and the back surface, wherein a linear length of the plurality of edges defines a perimeter of the substrate; a p-type doped emitter region disposed on the front surface and extending along the edges; and a n-type doped back surface field disposed on the back surface and extending along the edges under the p-type doped emitter region, such that a p/n junction is formed along at least 40% of the perimeter.

According to another embodiment, a method of manufacturing a solar cell is disclosed. The method comprises providing a substrate having a first surface, a second surface, opposite the first surface, and a plurality of edges therebetween, wherein a linear length of the plurality of edges defines a perimeter of the substrate, the substrate having a first conductivity; introducing ions of the first conductivity into the second surface and at least a portion of the plurality of edges; introducing ions of the second conductivity into the first surface and at least a portion of the plurality of edges, where the ions of the first conductivity diffuse more deeply into the substrate than the ions of the second conductivity; and thermally treating the substrate after the introducing steps so as to create a p/n junction along at least 40% of the perimeter.

### BRIEF DESCRIPTION OF THE FIGURES

For a better understanding of the present disclosure, reference is made to the accompanying drawings, which are incorporated herein by reference and in which:

FIG. 1 shows an embodiment of a solar cell according to one embodiment;

FIG. 2 shows a representative flowchart of an implant process used to make the solar cell of FIG. 1;

FIG. 3 shows a graph of concentration of implanted dopants as a function of depth;

FIG. 4 shows a graph of concentration of implanted dopants as a function of depth after thermal processing; and

FIG. 5 shows a representative flowchart of a diffusion process used to make the solar cell of FIG. 1.

### DETAILED DESCRIPTION

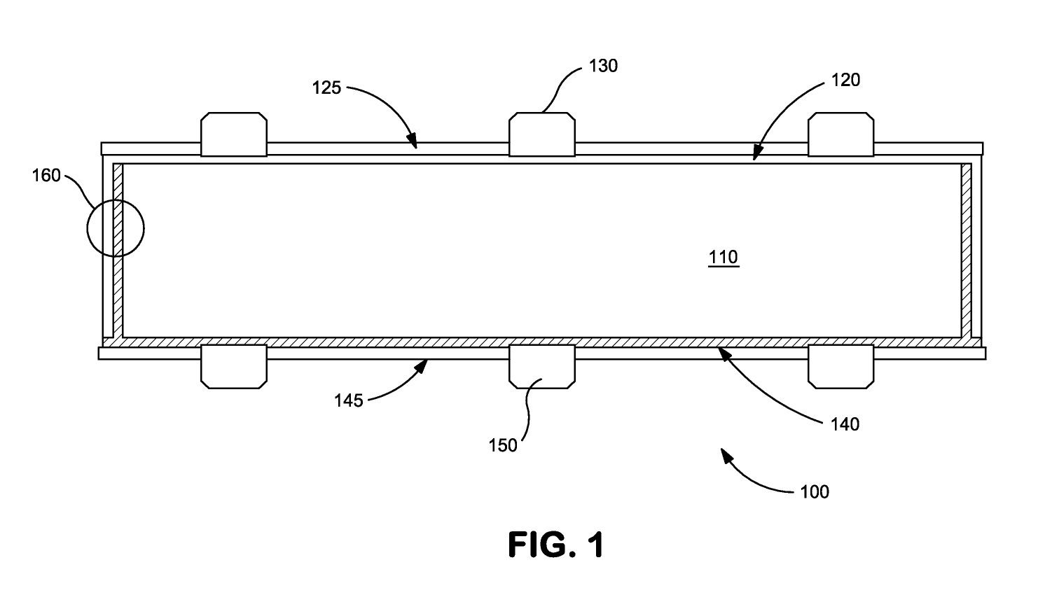

FIG. 1 shows a solar cell 100 according to one embodiment.

In this embodiment, the base silicon 110 may be an n-type conductor. In other embodiments, the base silicon 110 may be a p-type conductor. Located on the front surface of the solar cell 100 is an emitter region 120, which has the opposite conductivity of the base silicon 110. In other words, if an n-type base 110 is utilized, the emitter region 120 will be p-type doped. A passivation layer 125 is disposed on top of the emitter region 120. This passivation layer 125 may minimize reflection and maximize the light which enters the solar cell 100. Metal fingers 130 are disposed on the front surface of the solar cell 100 and are in electrical contact with the emitter region 120. These metal fingers 130 serve to collect majority carriers from the emitter region 120. A back surface field (BSF) region 140 is disposed on the opposite, or back, side of the solar cell 100. The BSF region 140 helps lateral mobility and minimizes recombination within the base silicon 100. A passivation layer 145 is also disposed on the BSF region 140. Metal contacts 150 are also disposed on the back surface and are in electrical contact with the BSF 140. In embodiments where solar cells are connected in series, the metal contacts 150 of one solar cell are electrically connected to the metal fingers 130 of another solar cell.

As stated above, the goal of this solar cell 100 is to maximize the area through which the reverse current passes in cases where the solar cell 100 is not producing electricity. It has been determined that reverse current more readily passes through regions where heavily doped emitter regions 120 abut heavily doped BSF regions 140.

However, in traditional solar cells, there is no region where the heavily doped emitter regions 120 abut heavily doped

BSF regions 140. In the embodiment of FIG. 1, the heavily n-doped region, which is the BSF 140 on the back surface, extends up the edges of the solar cell 100. Similarly, the heavily doped p-type emitter region also extends down the edges of the solar cell 100. In this way, there is a large area where these regions 120, 140 abut. For example, in a standard solar cell, there is more than 100 mm² of edge area. For example, the perimeter of a standard solar cell, which is defined as the linear length of all edges, may be about 62.4 cm, while the substrate may be about 0.02 cm in thickness. This results in a total area of more than 100 mm² of edge area.

Thus, this solar cell has a heavily doped BSF region 140 on one surface, a heavily doped emitter region 120 on the opposite side, and a p/n junction 160 formed along the edges of the solar cell 100, where both the heavily doped BSF region 140 and the heavily doped emitter region 120 are disposed. In some embodiments, the emitter region 120 is p-type doped, while the BSF region 140 is n-type doped. In these embodiments, along the sides, the emitter regions 120 may be disposed closer to the surface than the BSF region 140.

The intentional creation of a p/n junction 160 along the edges of the solar cell 100 provides a region where breakdown can occur, which provides significant amount of area for thermal dissipation.

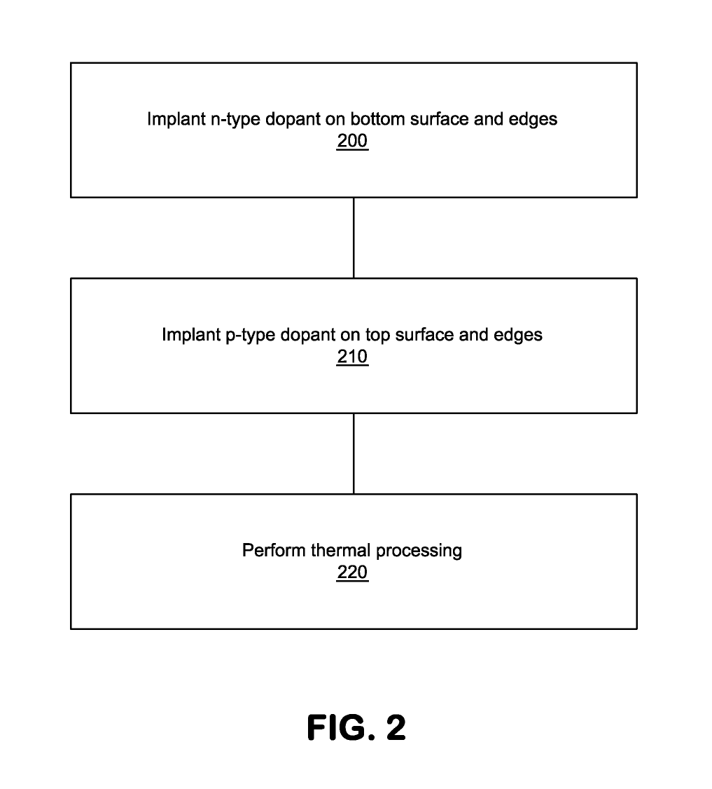

This p/n junction 160 along the edges of the solar cell can be created in a variety of ways. In one embodiment, ion implantation is used to create this solar cell 100. FIG. 2 shows a flowchart of a process that may be used to create this solar cell 100 using ion implantation. In some embodiments, the process of FIG. 2 may be performed using an n-type substrate to create this solar cell 100.

First, as shown in step 200, the n-type dopant is implanted into one surface and along the edges of the substrate.

Implantation along the edge may be accomplished in a number of ways. In one embodiment, the edges are implanted at the same time as the back surface. This is performed by careful selection of the angular distribution of the ion beam. In another embodiment, extra implant steps are performed to ensure that the edges are implanted. For example, the substrate may be tilted toward the ion beam to allow the ion beam to strike the edges. This tilting may be accomplished using a substrate holder having multiple degrees of movement. For example, the substrate holder may move the substrate such that each edge of the substrate moves in the path of the ion beam. Other techniques may also be used to insure that the back surface and the edges are both implanted with n-type dopant. In some embodiments, this n-type dopant is phosphorus, although other dopants may also be used.

In step 210, a p-type dopant is implanted into the opposite surface and also along the edges. As described above, various techniques may be used to insure that the p-type dopant is applied to the edges of the substrate as well as the front surface. In some embodiments, the p-type dopant is boron, although other dopants may also be used.

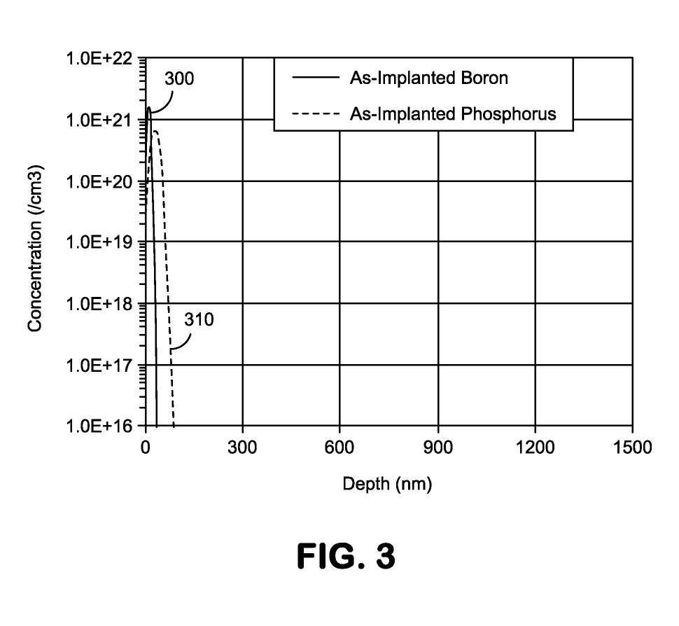

When processing the substrate, it may be advantageous to provide a higher dose of p-type dopant along the edges than n-type dopant. It is known that phosphorus diffuses more quickly and more deeply during a thermal anneal process than boron. In other words, the boron is more likely to be concentrated along the outer edge, while the phosphorus is likely to penetrate more deeply. To compensate for the counterdoping effect, a higher dose of boron may be used. FIG. 3 shows the concentrations of each dopant as a function of depth immediately following implant. As can be seen, the concentration of boron 300 is greater along the outer edge and decreases rapidly. The phosphorus 310 is more deeply implanted, but has a lower maximum concentration.

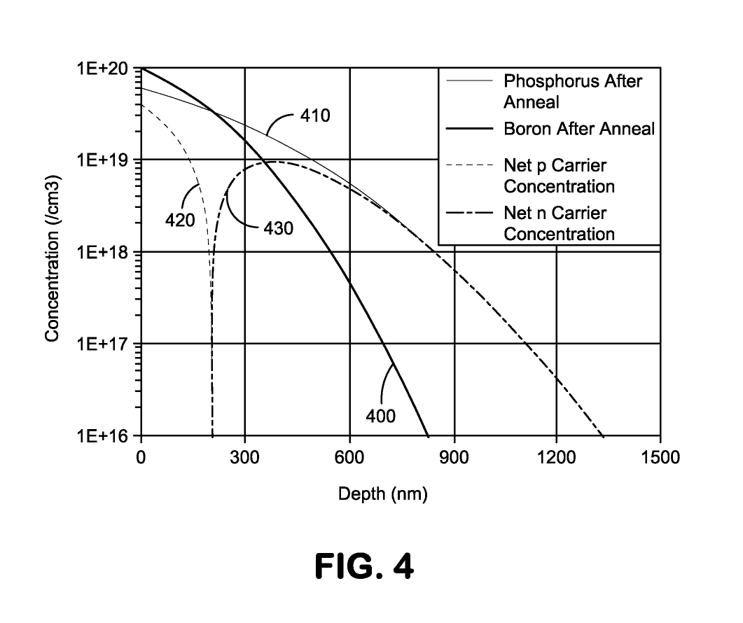

In step 220 of FIG. 2, a thermal processing cycle is performed. This thermal process may be an anneal cycle. This thermal process causes the dopants to diffuse into the substrates. FIG. 4 shows this effect. After anneal, the boron 400 has diffused into the edges of the substrate. However, boron only penetrates to a depth of less than 900 nm. In contrast, the phosphorus 410 diffused more deeply, to a depth of more than 1200 nm. Line 420 shows the net p-type carrier concentration. This line is determined by taking the effects of counterdoping into account, where line 420 is roughly equal to the concentration of boron less the concentration of phosphorus. Note that the net p-type concentration goes to 0 at a depth of about 200 nm, where the concentration of boron 400 equals the concentration of phosphorus 410. Similarly, the net n-type concentration 430 is roughly equal to the concentration of phosphorus 410 less the concentration of boron 400. The net n-type concentration starts at a depth of about 200 nm, reaches a maximum at about 350 nm and decreases thereafter.

The higher dose of boron 300 may be necessary to create the desired net p-type concentration 420, as shown in FIG. 4. The creation of adjacent regions 420, 430 provides the highly doped p/n junction needed to ensure Zener breakdown. Zener breakdown is an electrical breakdown in a reverse biased p-n diode, in which the electric field enables tunneling of electrons from the valence to the conduction band of a semiconductor, leading to a large number of free minority carriers, which results in a large increase in the reverse current. In some embodiments, the concentration of p-type carriers near the edge may be greater than 1E+18 atoms/cm³. In other embodiments, the concentration of p-type carriers may be between 5E+18 and 1E+21 atoms/cm³. In some embodiments, the concentration of n-type carrier beneath the p-doped region may be greater than 1E+18 atoms/cm³.

In some embodiments, a thermal processing step is also performed between the first implant step 200 and the second implant step 210. This anneal cycle may be used to insure that the n-type dopant diffuses more deeply into the substrate, prior to the implanting of p-type ions.

In some embodiments, a p-type substrate may be used to create the solar cell 100. In this embodiment, a different, slower diffusing n-type dopant may be used in place of phosphorus. For example, in one embodiment, arsenic may be used. In this embodiment, the p-type dopant, for example boron, may diffuse more rapidly than the n-type dopant. In other words, the more deeply heavily doped region may be the p-type region. By using a slower diffusing n-type dopant, the n-type region remains closer to the edge. In this embodiment, the implant steps 200, 210 shown in FIG. 2 may be reversed, such that the p-type dopant is implanted prior to the n-type dopant. Again, an additional anneal cycle may be added between these two implant steps to insure that the p-type dopant diffused more deeply than the n-type dopant.

In both cases, it may be preferable that the deeper heavily doped region has the same doping type, or conductivity, as the base material to ensure good electrical contact between the edge and the bulk of the substrate.

Stated differently, the solar cell is made using an underlying substrate. A first dopant, having a conductivity that is the same the underlying dopant is introduced, such as by ion implanting, into the substrate. Thus, if an n-type substrate is used, an n-type dopant is first introduced. If a p-type substrate is used, a p-type dopant is first introduced. This first dopant is introduced into one surface of the substrate, and along at least a portion of the perimeter. A thermal or anneal process may then be performed to allow the first dopant to diffuse deeply in the substrate, especially along the edges. A second dopant, having a conductivity that is opposite that of the first dopant and the underlying substrate, is then introduced in the opposite surface of the substrate and along at least a portion of the perimeter. This second dopant is selected to have slower diffusivity than the first dopant to insure that it remains closed to the edges. A second thermal or anneal process may be performed to diffuse the second dopant (or both dopants if this is the only anneal cycle). In some embodiments, the amount of ions of the second conductivity introduced into the substrate is greater than the amount of ions of the first conductivity to compensate for the effects of counterdoping.

The resulting solar cell has an underlying substrate having a first conductivity. It also has one surface that is doped with ions of the same conductivity to create a heavily doped region of the first conductivity. It has a second surface, opposite the first surface that is doped with ions of a second conductivity, opposite the first conductivity, to create a heavily doped region of the second conductivity. The solar cell also includes a p/n junction formed along at least a portion of the perimeter, where the more deeply diffused region has the first conductivity, with the edge having the second conductivity.

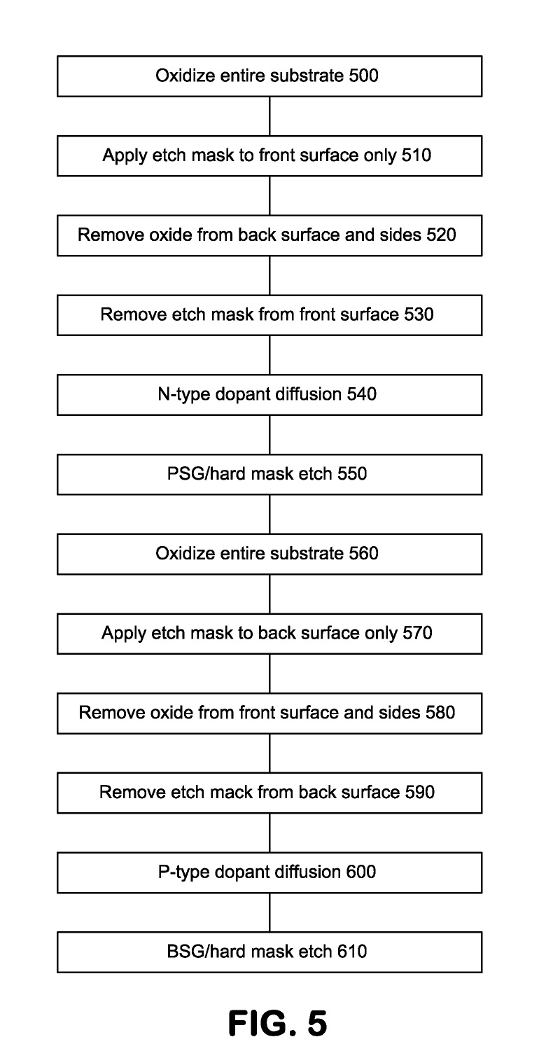

In another embodiment, the solar cell 100 may be created using diffusion, rather than ion implantation. FIG. 5 shows a flowchart of a representative diffusion process. In step 500, the substrate is oxidized on all surfaces. This creates a hard mask on all surfaces. A etch mask is then applied to the front surface, but not to the edges or back surface, as shown in step 510. The oxide layer is then removed, as shown in step 520. Since the front surface is masked, the oxide layer is not removed from this surface. The etch mask disposed on the front surface is then removed, as shown in step 530. An n-type dopant, such as phosphorus is then diffused into the substrate, as shown in step 540. Since an oxide layer is disposed on the front surface, phosphorus is not diffused into the front surface. At this time, the phosphosilicate glass (PSG) is removed from the edges and back surface and the oxide layer is removed from the front surface, as shown in step 550. The substrate is again oxidized to create a hard mask thereon, as shown in step 560. A mask is then applied to the back surface, but not the edges, as shown in step 570. The oxide layer is then removed from the front surface and edges, as shown in step 580. Since the back surface is masked, the oxide layer is not removed from this surface. The etch mask disposed on the back surface is then removed, as shown in step 590. A p-type dopant, such as boron, is then diffused into the substrate, as shown in step 600. Since an oxide layer is disposed on the back surface, boron is not diffused into the back surface. At this time, the borosilicate glass (BSG) is removed from the edges and front surface and the oxide layer is removed from the back surface, as shown in step 610.

This process may be used with an underlying substrate of either n-type or p-type conductivity. In either case, the dopants may be selected such that the dopant with the same conductivity as the underlying substrate diffused more rapidly and more deeply that the dopant having the opposite conductivity.

While the above describes a solar cell 100 where p/n junctions are formed along all of the edges, other embodiments are possible. For example, the p/n junctions may be formed on only a portion of the edges, such as, for example, one set of opposite edges. In another embodiment, the p/n junction may be formed in the entirety of the perimeter of the solar cell, where the perimeter is defined as the total linear length of all edges. In other embodiments, the p/n junction may be formed in at least 75% of the perimeter, such as, for example, along three edges. In other embodiments, the p/n junction may be formed in at least 50% of the perimeter, such as along two edges, for example, along two opposite edges. In other embodiments, the p/n junction may be formed in at least 40% of the perimeter, such as for example, along most of two edges. In other embodiments, the p/n junction may be formed in at least 25% of the perimeter, which may represent one edge. Other embodiments are also possible. By increasing the area in which the p/n junction is formed, more area is available to carry the reverse current, thereby reducing the heat generated in any particular area.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A solar cell, comprising:
a substrate having a first surface, an opposite second surface and a plurality of edges between said first surface and said second surface, wherein a linear length of said plurality of edges defines a perimeter of said substrate, said substrate having a first conductivity;
a first heavily doped region, having a second conductivity, opposite said first conductivity, disposed on said first surface and extending along said edges; and
a second heavily doped region, having said first conductivity, disposed on said second surface and extending along said edges under said first heavily doped region, such that a p/n junction is formed along at least 40% of said perimeter.

2. The solar cell of claim 1, wherein said first heavily doped region is doped with a first dopant, said second heavily doped region is doped with a second dopant, and said second dopant diffuses more rapidly than said first dopant.

3. The solar cell of claim 2, wherein said first conductivity is n-type, said first dopant comprises boron and said second dopant comprises phosphorus.

4. The solar cell of claim 2, wherein said first conductivity is p-type, said first dopant comprises arsenic and said second dopant comprises boron.

5. The solar cell of claim 1, wherein said p/n junction is formed along at least 50% of said perimeter.

6. The solar cell of claim 1, wherein said p/n junction is formed along at least 75% of said perimeter.

7. A solar cell, comprising:
a substrate having a front surface, an opposite back surface and a plurality of edges between said front surface and said back surface, wherein a linear length of said plurality of edges defines a perimeter of said substrate;
a p-type doped emitter region disposed on said front surface and extending along said edges; and
a n-type doped back surface field disposed on said back surface and extending along said edges under said p-type doped emitter region, such that a p/n junction is formed along at least 40% of said perimeter.

8. The solar cell of claim 7, wherein said p/n junction has an area of at least 100 mm².

9. The solar cell of claim 7, wherein each of said plurality of edges has a height and said p/n junction extends an entirety of said height.

10. The solar cell of claim 7, wherein said p-type doped emitter region disposed on said edges has a net p-type concentration of greater than 5E+18 atoms/cm³.

11. The solar cell of claim 10, wherein said n-type doped back surface field disposed on said edges has a net n-type concentration of 1E+19 atoms/cm³.

12. A method of manufacturing a solar cell, comprising:
providing a substrate having a first surface, a second surface, opposite said first surface, and a plurality of edges therebetween, wherein a linear length of said plurality of edges defines a perimeter of said substrate, said substrate having a first conductivity;
introducing ions of said first conductivity into said second surface and at least a portion of said plurality of edges;
introducing ions of said second conductivity into said first surface and at least a portion of said plurality of edges, where said ions of said first conductivity diffuse more deeply into said substrate than said ions of said second conductivity; and
thermally treating said substrate after said introducing steps so as to create a p/n junction along at least 40% of said perimeter.

13. The method of claim 12, wherein said ions are ion implanted into said substrate.

14. The method of claim 13, further comparing thermally treating said substrate after introducing ions of said first conductivity and before introducing ions of said second conductivity.

15. The method of claim 13, wherein said first conductivity is n-type, said ions of said first conductivity comprise phosphorus and said ions of said second conductivity comprise boron.

16. The method of claim 13, wherein said first conductivity is p-type, said ions of said first conductivity comprise boron and said ions of said second conductivity comprise arsenic.

17. The method of claim 12, wherein said ions are diffused into said substrate.
